(19) United States
(12) Patent Application Publication
(10) Pub. No.: US 2005/0068727 A1
(43) Pub. Date: Mar. 31, 2005

(54) Heat dissipating structure of accelerated graphic port card

(76) Inventor: Chien-Chun Yu, Shulin City (TW)

Correspondence Address: Chien-Chun Yu, P.O.Box No. 6-57, Junghe, Taipei, 235, TW

(21) Appl. No.: 10/671,673

(22) Filed: Sep. 29, 2003

(51) Int. Cl. H05K 7/20

(52) U.S. Cl. 361/689; 361/696

(57) ABSTRACT

A heat dissipating structure of accelerated graphics port (AGP) card, disposed at the AGP card for dissipating heat with respect to a certain chip therein, at least includes an extruded aluminum heat dissipating section and a fan. The invention is characterized that, at least one heat conducting pipe is disposed at a lower portion of the extruded aluminum heat dissipating section, and extended to a rear side of the AGP card; and thermal energy produced by the AGP card chip is conducted by the heat conducting pipes to cooling fins at the rear side of the AGP card, thereby increasing an effective heat dissipating area for enhancing heat dissipation effects.

### BACKGROUND OF THE INVENTION

(a) Field of the Invention

The invention relates to a heat dissipating structure of accelerated graphics port (AGP) card, and more particularly, to heat dissipating structure having an extruded aluminum heat dissipating section. Using the extruded aluminum heat dissipating section, thermal energy is conducted to additionally provided cooling fins at a rear side of the AGP card via heat conducting pipes, thereby increasing an effective heat dissipating area for enhancing heat dissipation effects.

(b) Description of the Prior Art

Referring to FIG. 1 showing a prior computer accelerated graphics port (AGP) card, the structure comprises a chip b. To use the structure, an AGP card a is inserted into an AGP Pro of a motherboard, and the computer may then drive a monitor to display images. However, the chip b emits thermal energy during operations thereof. Therefore, in order to prevent the device from damages caused by overheating, certain industrialists assemble a heat sink c at the chip b. Using heat conduction by direct contact between the heat sink c and the chip b, thermal energy is dissipated in conjunction with a fan disposed therein. Yet, such heat dissipating structure and method are considered insufficient for having inadequacies when put to use, and hence the prior invention can be further advanced.

### SUMMARY OF THE INVENTION

The primary object is to provide a heat dissipating structure of accelerated graphics port (AGP) card, in that the heat dissipating structure has an increased effective heat dissipating area for accelerating heat dissipation effects.

To accomplish the aforesaid object, according to the invention, at least one heat conducting pipe is fixed at a lower portion of an extruded aluminum heat dissipating section that is in contact with an AGP card chip, and has the other unfixed end extended to a rear side of the AGP card. Heat conducting pipes located at the rear side of the AGP card are fastened to a set of cooling fins. The heat conducting pipes are for absorbing thermal energy produced by the AGP card chip and conducting the thermal energy to the cooling fins at the rear side of the AGP card, thereby increasing an effective heat dissipating area for enhancing heat dissipation effects.

### BRIEF DESCRIPTION OF THE DRAWINGS

FIG. 1 shows an elevational view of an embodiment illustrating an accelerated graphics port (AGP) card of a prior invention.

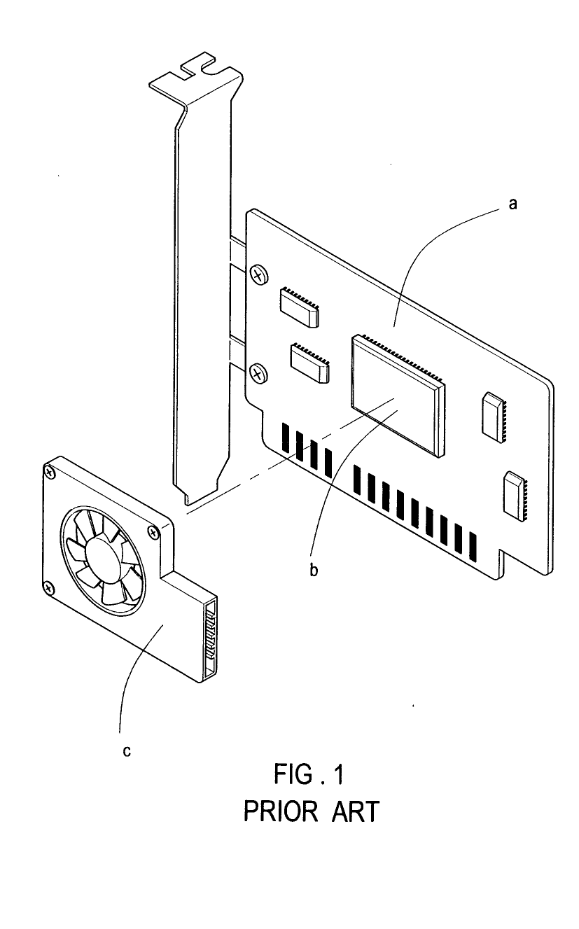

FIG. 2 shows an exploded elevational view illustrating a heat dissipating structure of AGP card according to the invention.

FIG. 3 shows an elevational view illustrating a heat dissipating structure of AGP card in an embodiment according to the invention.

FIG. 4 shows a planar side view of the embodiment shown in FIG. 3.

FIG. 5 shows an exploded partial elevational view illustrating another embodiment according to the invention.

FIG. 6 shows an elevational view of yet another embodiment according to the invention.

### DETAILED DESCRIPTION OF THE PREFERRED EMBODIMENTS

To better understand the structure, device and characteristics of the invention, detailed descriptions of preferred embodiments shall be given with the accompanying drawings below.

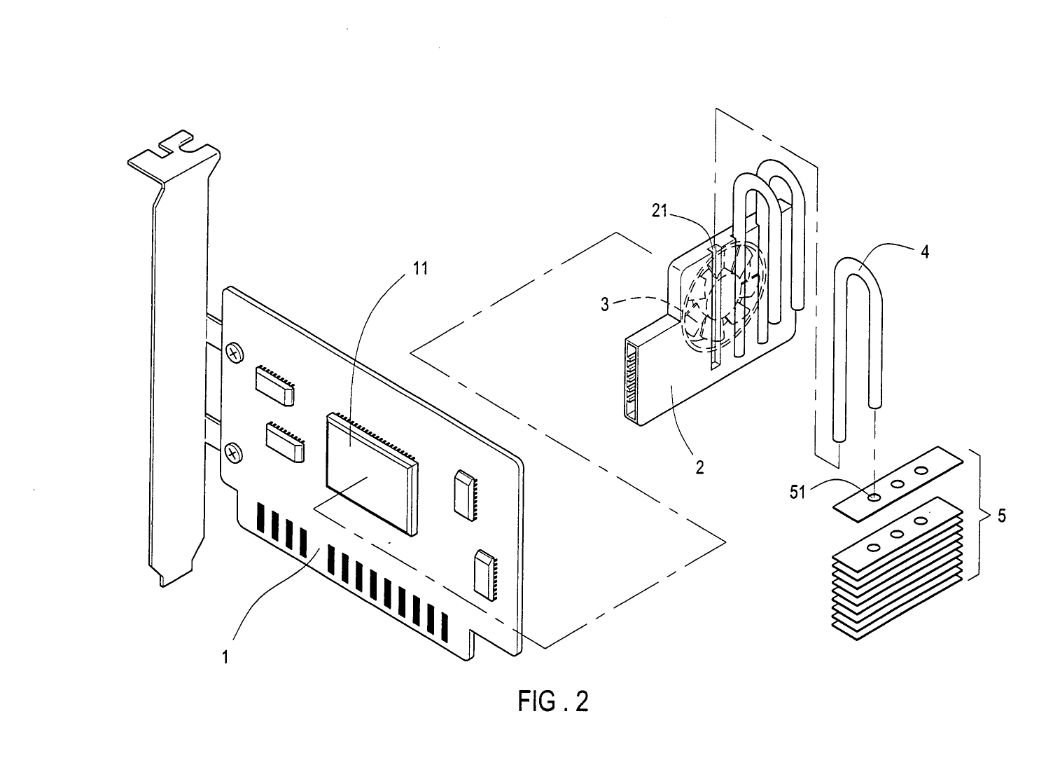

Referring to FIGS. 2 to 4, a heat dissipating structure of accelerated graphics port (AGP) card disposed at an AGP card 1 in order to dissipate heat with respect to a chip 11 therein, at least comprises an extruded aluminum heat dissipating section 2 and a fan 3. The characteristics of the invention are that, the extruded aluminum heat dissipating section 2 has at least one groove 21 at a lower surface thereof; each groove 21 is provided with a fixed heat conducting pipe 4 at an interior thereof; the other unfixed end of each heat conducting pipe 4 is extended and bent along the AGP card 1 to reach a rear side of the AGP card 1; a portion of each heat conducting pipe 4 extended to the rear side of the AGP card 1 is connected and fastened with a set of cooling fins 5; and the cooling fins 5 are perforated with at least one opening 51, so as to have the heat conducting pipes 4 located at the rear side of the APG card 1 penetrated and fasten the cooling fins 5.

When the aforesaid structure is assembled for applications, thermal energy produced by the chip 11 at the APG card 1 is immediately absorbed by the closely located extruded aluminum heat dissipating section 2. Using the heat conducting pipes 4 having better heat conductivity, the thermal energy is then conducted to the cooling fins 5 at the rear side of the APG card 1. Thus, an effective heat dissipating area is increased for directly enhancing heat dissipation effects of the heat dissipating structure with respect to the APG card chip 11.

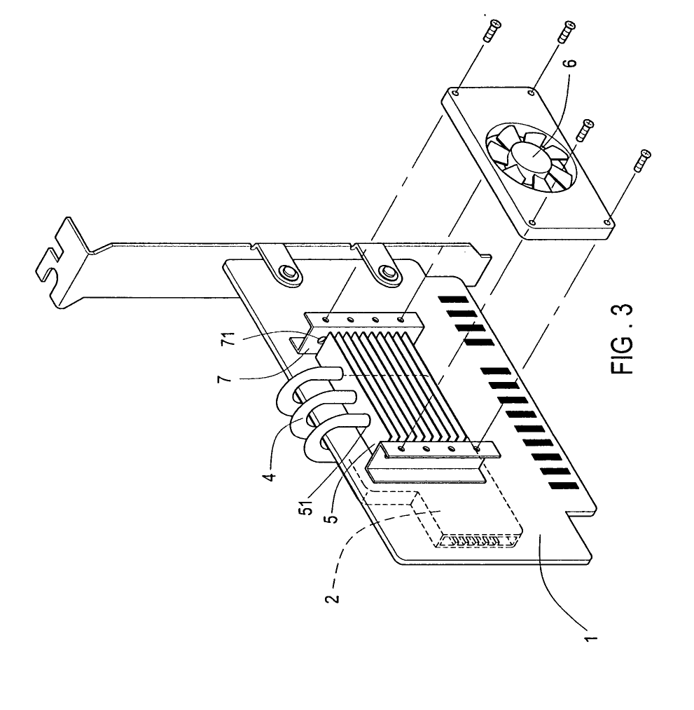

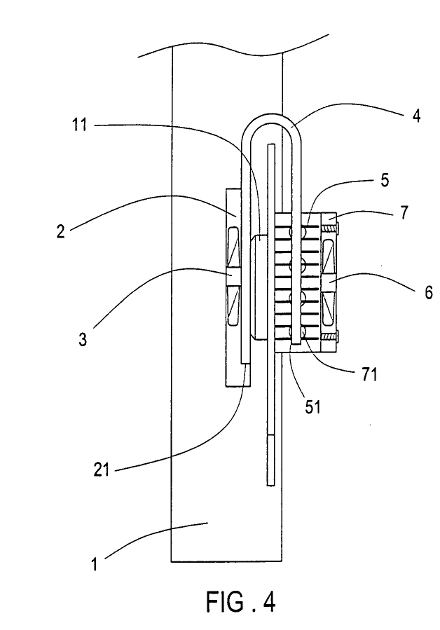

Referring to FIGS. 3 and 4, in another embodiment according to the invention, an additional fan 6 is provided above the cooling fins 5 at the rear side of the AGP card 1. The fan 6 directly blows the cooling fins 5 at the rear side of the AGP card 1, and heat dissipation effects of the cooling fins 5 are again reinforced.

Furthermore, the cooling fins 5 at the rear side of the AGP card 1 are further provided with a support frame 7 at two sides thereof, respectively. The aforesaid fan 6 is fixed to the supporting frames 7, so as to facilitate assembly of the structure as well as avoiding overloading of the heat conducting pipes 4 for lengthening lifespan thereof. Each of the supporting frames 7 may be perforated with a plurality of ventilation openings 71, such that ventilation is promoted for increasing heat dissipation effects.

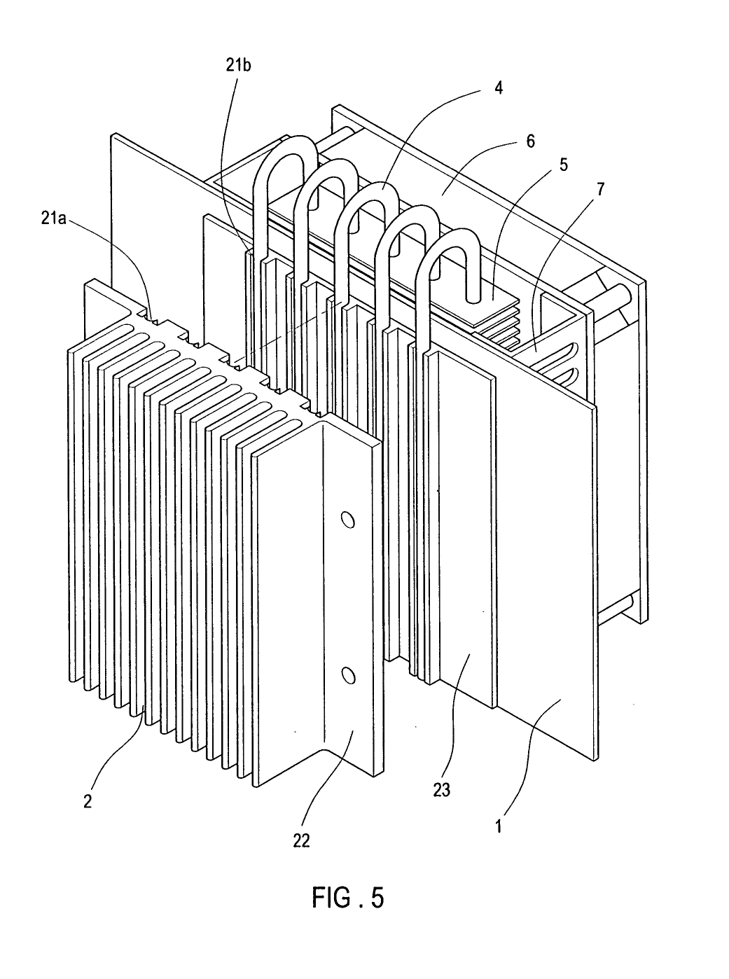

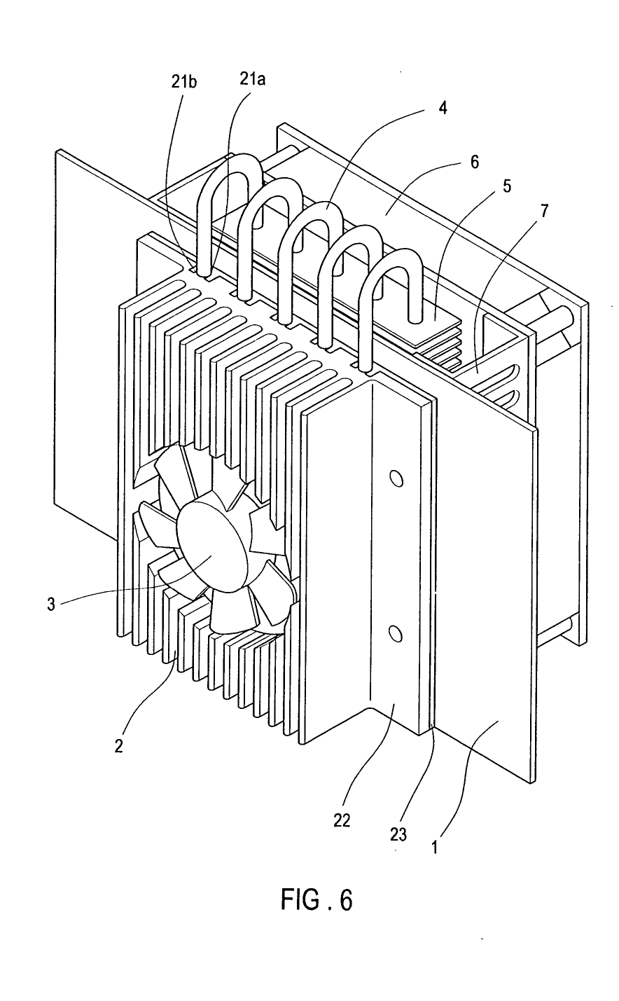

Referring to FIGS. 5 and 6, the extruded aluminum heat dissipating section 2 may be formed as a two-part structure, which includes a cooling fin main body 22 and a bottom panel 23. The cooling fin main body 22 is disposed with a plurality of grooves 21a at a lower surface thereof, whereas the bottom panel 23 is disposed with a plurality of corresponding grooves 21b. After assembling the structure, a channel-like space is formed between each groove 21a and each groove 21b, with the channel-like spaces accommodating and fastening the heat conducting pipes 4. Moreover, referring to FIG. 2, the extruded aluminum heat dissipating section 2 may either be disposed with the fan 6 or not disposed with the fan 6 at a top portion thereof.

Conclusive from the above descriptions, the heat dissipating structure of AGP card effectively utilizes spaces for increasing functions thereof. It is of course to be understood that the embodiments described herein are merely illustrative of the principles of the invention and that a wide variety of modifications thereto may be effected by persons skilled in the art without departing from the spirit and scope of the invention as set forth in the following claims.

1. A heat dissipating structure of accelerated graphics port (AGP) card, disposed at the AGP card for dissipating heat with respect to a certain chip therein; at least comprising an extruded aluminum heat dissipating section and a fan; and being characterized that:
at least one heat conducting pipe is disposed at a lower portion of the extruded aluminum heat dissipating section, and extended to a rear side of the AGP card; and thermal energy produced by the AGP card chip is conducted by the heat conducting pipes to cooling fins at the rear side of the AGP card, thereby increasing an effective heat dissipating area for enhancing heat dissipation effects.

2. The heat dissipating structure of AGP card in accordance with claim 1, wherein the cooling fins at the rear side of the AGP card is provided with a fan.

3. The heat dissipating structure of AGP card in accordance with claim 2, wherein the cooling fins at the rear side of the AGP card further have a support frame at two sides thereof, respectively, and the support frames are for fixing the fan.

4. The heat dissipating structure of AGP card in accordance with claim 3, wherein each support frame is perforated with a plurality of ventilation openings at a side wall thereof.

5. The heat dissipating structure of AGP card in accordance with claim 1, wherein the extruded aluminum heat dissipating section comprises a cooling fin main body and a bottom panel; the cooling fin main body is disposed with a plurality of grooves at a lower surface thereof, whereas the bottom panel is disposed with a plurality of corresponding grooves; and after assembling the structure, a channel-like space is formed between each groove and each groove, with the channel-like spaces accommodating and fastening the heat conducting pipes.
